(19) United States
(12) Patent Application Publication
(10) Pub. No.: US 2025/0374806 A1
(43) Pub. Date: Dec. 4, 2025

(54) DISPLAY DEVICE, ELECTRONIC DEVICE AND METHOD OF MANUFACTURING COVER WINDOW

(71) Applicant: Samsung Display Co., Ltd., Yongin-Si (KR)

(72) Inventors: Byung Hoon KANG, Yongin-si (KR); Sang Hoon KIM, Yongin-si (KR); Tae-Hyeog JUNG, Yongin-si (KR); Seong Jin HWANG, Yongin-si (KR)

(21) Appl. No.: 19/083,452

(22) Filed: Mar. 19, 2025

(30) Foreign Application Priority Data
May 30, 2024 (KR) 10-2024-0071091

(51) Int. Cl. H10K 59/80; H10K 59/12; H10K 102/00

(52) U.S. Cl. CPC H10K 59/873; H10K 59/1201; H10K 59/8792; H10K 2102/311

(57) ABSTRACT

A display device comprises a display panel including a folding area and a non-folding area, and a cover window on the display panel and including a folding portion and a non-folding portion. The cover window comprises a glass layer, a coating layer on the glass layer, an adhesive layer on the coating layer, and a protective layer on the adhesive layer. The thickness of the coating layer is 30 μm to 90 μm. Edges of the protective layer, the adhesive layer, and the coating layer are aligned. The folding portion includes an inner surface that is compressed when folded and an outer surface that is stretched when folded. The folding portion overlaps the folding area, and the non-folding portion overlaps the non-folding area.

### CROSS-REFERENCE TO RELATED APPLICATION

This application claims priority to and the benefit of Korean Patent Application No. 10-2024-0071091 filed at the Korean Intellectual Property Office on May 30, 2024, the entire contents of which are incorporated herein by reference.

### BACKGROUND OF THE INVENTION

### Field of the Invention

The present disclosure relates to a display device, an electronic device and a method of manufacturing a cover window.

### Description of the Related Art

Display devices such as organic light emitting displays and liquid crystal displays generally include display panels that are manufactured by forming multiple layers and elements on a substrate. Recently, flexible display panels and display devices including the flexible display panels have been developed. Flexible display devices may include bendable display devices, foldable display devices, rollable display devices, and stretchable display devices, depending on their use or shape. A foldable display device may be folded and unfolded like a book. Foldable display devices have the advantage of being able to be folded and carried compactly and unfolded when in use to enjoy a wide screen.

### SUMMARY OF THE INVENTION

A cover window usable in a foldable display device may include thin glass to enable folding, but the thin glass may increase the risk of the cover window breaking if subjected to an impact, such as if an object, such as a pen, is dropped on the thin cover window. Embodiments of the present disclosure may improve impact resistance by introducing a coating layer to a cover window used in a foldable display device and may provide an efficient manufacturing method for the cover window and the foldable display device including the cover window.

A display device according to an embodiment comprises a display panel including a folding area and a non-folding area, and a cover window disposed on the display panel and including a folding portion and a non-folding portion. The cover window may comprise a glass layer, a coating layer disposed on the glass layer, an adhesive layer disposed on the coating layer, and a protective layer disposed on the adhesive layer. The thickness of the coating layer may be 30 μm to 90 μm, and edges of the protective layer, the adhesive layer, and the coating layer may include an aligned first side surface. The folding portion overlaps the folding area and may include an inner surface that is compressed when folded and an outer surface that is stretched when folded, and the non-folding portion overlaps the non-folding area.

The thickness of the coating layer may be 30 μm to 60 μm.

The coating layer may include a resin, and the modulus of the coating layer may be 500 KPa to 1 GPa.

The elongation rate of the coating layer may be 1.0% to 4.0%.

The thickness of the glass layer may be 25 μm to 35 μm.

The thickness of the adhesive layer may be 25 μm to 50 μm.

The thickness of the protective layer may be 50 μm to 80 μm.

A light blocking layer may be further included between the protective layer and the adhesive layer, and a part of the light blocking layer may define at least one edge of a light transmitting area of the cover window.

The light blocking layer may have a second side surface aligned with the first side surface.

The coating layer may be in contact with the upper surface of the glass layer.

The adhesive layer may be in contact with the upper surface of the coating layer.

The protective layer may be in contact with the upper surface of the adhesive layer.

A method of manufacturing a cover window according to an embodiment comprises printing a light blocking material layer on a protective material layer, laminating an adhesive material layer on the protective material layer, applying a coating material layer on the adhesive material layer, laminating a glass layer on the coating material layer, curing the coating material layer, and simultaneously laser cutting the protective material layer, the adhesive material layer, and the coating material layer along a cutting line to form a cover window.

The coating material layer may include a resin bump portion disposed at ends of the coating material layer, and the laser cutting may remove the resin bump portion.

The cutting line may be a line crossing the protective material layer, the adhesive material layer, and the coating material layer in the thickness direction.

In the laser cutting step, the edge of the glass layer may be spaced apart from the cutting line.

In the laser cutting step, the glass layer may also be laser cut along the cutting line.

The coating material layer may be 30 μm to 90 μm thick.

The coating material layer may be 30 μm to 60 μm thick.

The coating material layer may include a resin, and the modulus of the coating material layer may be 500 KPa to 1 GPa.

An electronic device according to an embodiment comprises a memory, a processor executing an application stored in the memory and a display device comprising a display module outputting video information provided by the application, wherein the display device comprises a display panel including a folding area and a non-folding area and a cover window disposed on the display panel and including a folding portion and a non-folding portion, wherein the cover window comprises a glass layer, a coating layer disposed on the glass layer an adhesive layer disposed on the coating layer and a protective layer disposed on the adhesive layer, wherein the thickness of the coating layer is 30 μm to 90 μm, edges of the protective layer, the adhesive layer, and the coating layer are aligned at a first side surface, the folding portion includes an inner surface that is compressed when folded and an outer surface that is stretched when folded, the folding portion overlaps the folding area, and the non-folding portion overlaps the non-folding area.

Embodiments in accordance with the present disclosure may minimize curling of the glass layer and improve impact resistance by introducing a protective layer of a certain thickness into a cover window used in a display device and may effectively manufacture the protective layer.

### BRIEF DESCRIPTION OF THE DRAWINGS

FIG. 1 is a perspective view schematically illustrating a display device according to an embodiment.

FIG. 2 is a schematic top plan view of a display panel according to an embodiment.

FIG. 3 is a cross-sectional view of a display device according to an embodiment, where the display device shown in FIG. 1 is cut along line A1-A2.

FIG. 4 is a top plan view of a cover window of a display device according to an embodiment when the display device is not folded.

FIG. 5 is a side view of a cover window of a display device according to an embodiment when folded in a first direction DR1.

FIG. 6 is a cross-sectional view of a cover window according to an embodiment.

FIG. 7 is a flowchart of a method of manufacturing a display device including a cover window.

FIGS. 8 and 9 are cross-sectional views illustrating a method of manufacturing a display device according to an embodiment.

FIG. 10 is a table showing the degree of strain of each layer of a display device according to the force applied to the display device and the thickness of the coating layer when the display device is folded.

FIG. 11 is a table showing improvement of the impact resistance of the glass layer when introducing a coating layer.

FIG. 12 is a block diagram of an electronic device according to some embodiments.

FIG. 13 shows schematic diagrams of electronic devices according to various embodiments

### DETAILED DESCRIPTION OF EMBODIMENTS

This disclosure hereinafter describes embodiments that are illustrated in the drawings. As those skilled in the art would realize, the described embodiments may be modified in various ways without departing from the spirit or scope of the disclosure. To concisely describe such embodiments, parts that may be well known or may be irrelevant to the most important aspects of this description may be omitted in the following.

Like reference numerals and/or reference characters shown in various figures refer to like or similar constituent elements, and description of such elements shown in a figure may omitted if the elements are described with reference to another figure. Further, sizes and thicknesses of constituent members as shown in the accompanying drawings may be enlarged or reduced for better understanding and ease of description. In particular, the thicknesses of layers, films, panels, regions, etc., may be enlarged or reduced for clarity of illustration. Accordingly, the disclosure is not limited to the illustrated sizes and thicknesses of components.

An element such as a layer, film, region, or substrate referred to as being “on” another element may be directly on the other element or intervening elements may also be present. In contrast, when an element is referred to as being “directly on” another element, no intervening elements are present. Further, in the specification, the word “on” or “above” means positioned on or below the object portion as illustrated and does not necessarily mean positioned on the upper side of the object portion based on the direction of gravity.

Unless explicitly described to the contrary, the word “comprise” and variations such as “comprises” or “comprising” imply the inclusion of stated elements but not the exclusion of any other elements.

Further, throughout the specification, the phrase “plan view” means when an object portion is viewed from above, and the phrase “in a cross-sectional view” refers to when a cross-section taken by cutting an object portion and viewing the cut surface.

In this specification, “connected” may means that two or more components are directly connected or that two or more components are connected indirectly through other components. Further, objects that are connected may be physically connected or electrically connected, and connected objects may be referred to by different names depending on the location or function and may be substantially integral to each other.

In addition, throughout the specification, a portion of a wire, layer, film, region, plate, component, etc., said to “extend in a first direction or a second direction” does not indicate only a straight shape extending straight in the stated direction but may indicate a structure that generally extends along the first direction or the second direction. For example, an object that extends in a particular direction may be a structure that is bent at a portion, has a zigzag structure, or extends while including a curved structure.

In addition, the present specification intends to include not only the illustrated embodiments but also any electronic device (e.g., a mobile phone, TV, monitor, notebook computer, etc.) including a display device, a display panel, etc. described in the specification and any electronic device including a display device or a display panel manufactured by the manufacturing method described in the specification.

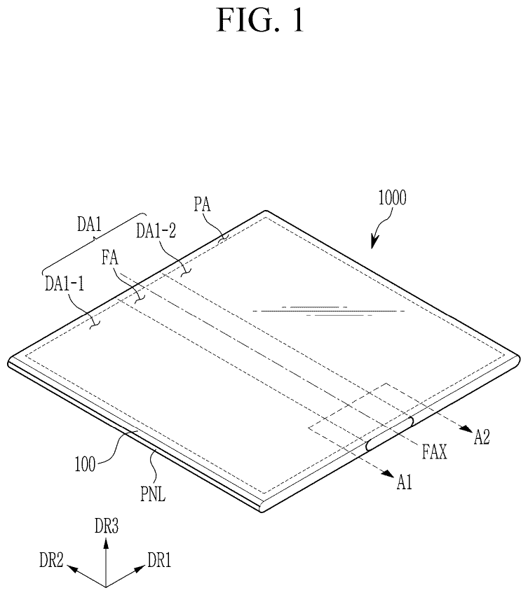

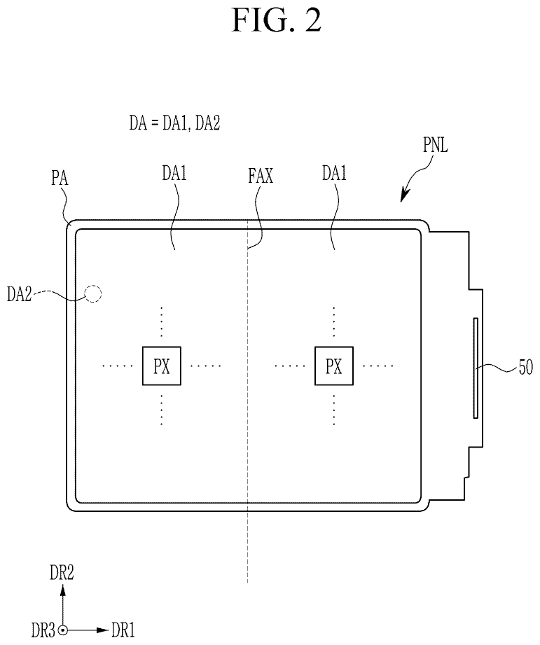

FIG. 1 is a perspective view schematically illustrating a display device according to an embodiment. FIG. 2 is a schematic top plan view of a display panel according to an embodiment.

A display device 1000 according to an embodiment is a device displaying a moving image or a still image and may be used as the display screen of not only portable electronic devices, such as a mobile phone, a smartphone, a tablet personal computer (PC), a mobile communication terminal, an electronic notebook, an e-book, a portable multimedia player (PMP), a navigation system, and an ultra-mobile PC (UMPC), but also various products such as a television, a laptop, a monitor, a billboard, and the Internet of things (IoT). In addition, the display device 1000 according to an embodiment may be used in wearable devices, such as a smartwatch, a watch phone, a glasses-type display, and a head-mounted display (HMD). In addition, a display device according to an embodiment may be used as a car's instrument panel, a center information display (CID) placed on a car's center fascia or dashboard, a room mirror display replacing a car's side mirror, or a display placed on the back surface of a front seat as entertainment for a car's rear seat.

Referring to FIG. 1, the display device 1000 may display an image on a display surface parallel to each of a first direction DR1 and a second direction DR2, and the image may be visible from a third direction DR3. The display surface on which an image is displayed may correspond to a front surface of the display device 1000, and the image may include a still image or a dynamic image.

The display device 1000 according to an embodiment may detect a user's input applied to the display device 1000. The user's input may include various types of external inputs, such as light, heat, pressure, or a touch by a part of the user's body. In an embodiment, the user's input may be input by the user's hand applied to the front surface of the display device 1000 or input by a pen such as a stylus used by the user, but the present disclosure is not limited thereto. Additionally, the display device 1000 may detect a user's input applied to the side surface or back surface of the display device 1000 depending on the structure of the display device 1000.

In an embodiment, the display device 1000 may include a display area DA and a peripheral area PA (hereinafter also referred to as a non-display area). The display area DA is an area where an image is displayed and may also be an area where an external input is detected. The display area DA may be an area where a plurality of pixels, which are described further below, are arranged.

The display area DA may include a first display area DA1 and a second display area (see DA2 in FIG. 2).

A plurality of light emitting diodes and a plurality of pixel circuits that provide current to the plurality of light emitting diodes are formed in the first display area DA1. Here, one light emitting diode and one pixel circuit are referred to as a pixel PX (see FIG. 2). One pixel circuit may correspond to one light emitting diode in the first display area DA1.

The first display area DA1 may include a display area DA1-1, a display area DA1-2, and a folding area FA. The display area DA1-1 and the display area DA1-2 may be disposed at the left and right sides, respectively, relative to a folding axis FAX, and the folding area FA may be disposed between the display area DA1-1 and the display area DA1-2. When the display device 1000 is folded outwardly about the folding axis FAX, the display area DA-1 and the display area DA1-2 are disposed at two opposite sides, in the third direction DR3, of the display device 1000, and portions of an image may be visible from two opposite directions. When the display device 1000 is folded inwardly about the folding axis FAX, the display area DA1-1 and the display area DA1-2 may be concealed.

Depending on the embodiment of the display device 1000, the display area DA may further include a second display area (see DA2 in FIG. 2), and this embodiment is described below with reference to FIG. 2.

FIG. 2 illustrates the planar structure of a display panel PNL that may be included in the display device 1000. FIG. 2 particularly shows a top plan view of a flexible display panel according to an embodiment.

The display panel PNL, which may be included in the display device 1000, also has the display area DA disposed on the front surface, and the display area DA includes the first display area (DA1; hereinafter also referred to as a main display area) and the second display area (DA2; hereinafter also referred to as a component area).

A plurality of light emitting diodes and a plurality of pixel circuits that provide currents to the plurality of light emitting diodes are in the first display area DA1. Here, each pixel PX may include at least one light emitting diode and at least one pixel circuit. The second display area DA2 may include a light transmission area and may additionally include pixels that display an image. The second display area DA2 may be an area that at least partially overlaps an optical element such as a camera or optical sensor. FIG. 2 shows the second display area DA2 as being provided in a circular shape on the left side of the display device 1000, but the present disclosure is not limited thereto. The second display area DA2 may include various numbers of separated areas having various shapes depending on the number and shape of optical elements associated with the display device 1000.

The display device 1000 may receive an external signal required for an optical element through the second display area DA2 or may provide a signal output from the optical element to the outside of the display panel PNL. In an embodiment, the second display area DA2 overlaps the light transmission area, i.e., is part of the display area DA, thereby reducing the required area of the peripheral area PA.

The peripheral area PA may be further disposed outside the display area DA. In the embodiment of FIG. 2, the second display area DA2 is surrounded by the first display area DA1 such that the area of the display area DA is not reduced by the second display area DA2, and the area of the peripheral area PA does not need to be increased to accommodate an optical device associated with the second display area DA2.

Referring to FIGS. 1 and 2, in an embodiment, the display device 1000 may be a foldable flexible display device. As described above, the display device 1000 may be folded outward or inward about the folding axis FAX. When folded outward based on the folding axis FAX, the display surface of the display device 1000 is disposed on the outside in the third direction DR3 so that images may be displayed in both directions. If the display device 1000 is folded inward based on the folding axis FAX, the display surface may be concealed.

The peripheral area PA is shown outside the display area DA, and a driver 50 may be formed in the peripheral area PA as shown in FIG. 2. The peripheral area PA is disposed outside the display area DA and may include the driver 50, connection wiring, and a bending area. Depending on the embodiment, the portion of a display panel DP where the driver 50 is disposed may be folded backward to position the driver 50 behind the display area DA when the display device 1000 is completed.

FIG. 2 shows the driver 50 as being disposed in the peripheral area PA on one side of the display area DA and shows the driver 50 extending in a direction parallel to the folding axis FAX, but the position, orientation, and shape of the driver 50 may be changed in various ways.

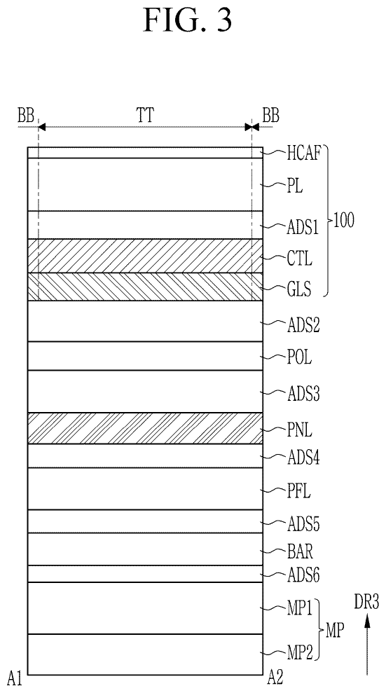

Hereinafter, the structure of the display device according to an embodiment is described with reference to FIG. 3 along with FIGS. 1 and 2 described above. FIG. 3 is a cross-sectional view of a display device according to an embodiment, where the display device is cut along a line A1-A2 shown in FIG. 1.

The display device 1000 according to an embodiment may have the display panel PNL with a back surface on a protective film PFL, a barrier layer BAR, and a metal plate MP, and a polarizer POL and a cover window 100 may be disposed on the front surface of the display panel PNL. A third adhesive layer ADS may attach the polarizer POL to the display panel PNL, a fourth adhesive layer ADS4 may attach the display panel PNL to the protective film PFL, a fifth adhesive layer ADS5 may attach the protective film PFL to the barrier layer BAR, and a sixth adhesive layer ADS6 may attach the barrier layer BAR to the metal plate MP.

Adhesive layers ADS1, ADS2, ADS3, ADS4, ADS5, and ADS6 may include an optically clear adhesive (OCA), an optically clear resin (OCR), or a pressure sensitive adhesive (PSA). More specifically, the adhesive layers ADS1, ADS2, ADS3, ADS4, ADS5, and ADS6 may include, for example, an acryl-based material, a silicon-based material, rubber, polyurethane, vinyl acetate, epoxy resin, and a polymer resin such as styrene-butadiene-styrene (SBS).

The display panel PNL may include a display part on which pixels are disposed to display an image, a touch sensor disposed on the upper part of the display part to detect an external input, and the driver (50 in FIG. 2). As shown in FIG. 1, the front surface of the display panel PNL may include the display area DA and the peripheral area PA. The display area DA may be an area where pixels operate according to electrical signals and emit light. In an embodiment, the pixels are below a touch sensor of the display panel PNL and emit light in the third direction DR3, and at the same time, the touch sensor is disposed above the pixels in the third direction DR3 so that external input may be detected.

The protective film PFL disposed on the back surface of the display panel PNL is a layer capable of strengthening the impact resistance applied to the display panel PNL and may also be referred to as an impact resistance layer. The protective film PFL may be formed of polyimide (PI) or polyurethane or may be formed of a mixed resin containing polyimide (PI) or polyurethane. Meanwhile, depending on the embodiment, the protective film PFL may include a copolymer including at least one resin containing a urethane functional group. Here, the urethane functional group may include —NH (peak (3200˜3300 cm⁻¹)) or —C═O (peak (1700˜1750 cm⁻¹)). Additionally, the protective film PFL may be formed of polyethylene terephthalate.

The barrier layer BAR is disposed on the back surface of the protective film PFL and may serve to alleviate impacts applied from the back surface of the display panel PNL. According to the embodiment, the barrier layer (BAR) may be black to prevent external light from reaching the back surface of the display panel PNL and may also prevent light from the display panel PNL from being reflected from the back surface to the front surface of the display panel PNL. The barrier layer BAR may be formed of polyimide (PI) and may have a thickness of approximately 35 μm.

The metal plate MP may be attached to the back surface of the barrier layer BAR, and the metal plate MP may primarily serve to maintain the display device 1000 in a desired shape for a folded state when the display device 1000 is folded about the folding axis FAX, and the metal plate MP may include a thin metal plate. The metal plate MP may include at least one layer, for example, an upper metal plate MP1 and a lower metal plate MP2. The upper metal plate MP1 may have a thickness of approximately 150 μm, and the lower metal plate MP2 may have a thickness of approximately 113 μm.

The polarizer POL may be disposed between the cover window 100 and the display panel PNL, which may prevent external light from entering the display panel PNL and being reflected and presented to the user's eye, deteriorating the display quality or revealing the internal structure of the display panel PNL. Depending on the embodiment, the polarizer POL may be omitted.

The cover window 100 is disposed on the front surface of the display panel DP and the polarizer POL, and the cover window 100 may be attached on the polarizer POL by the second adhesive layer ADS2.

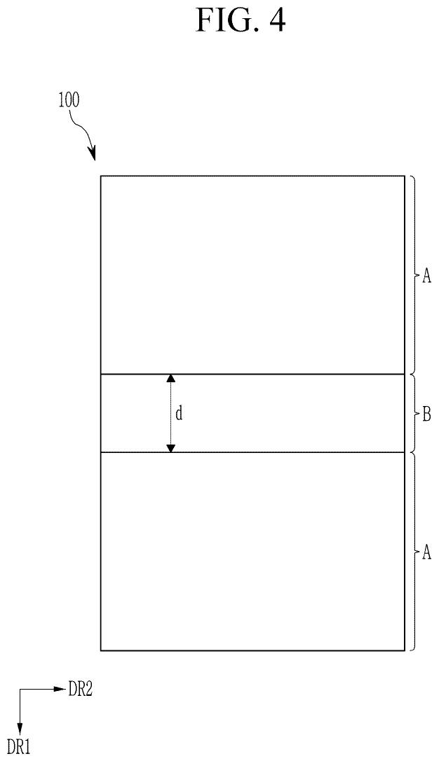

The cover window 100 may include a glass layer GLS, a coating layer CTL, a first adhesive layer ADS1, and a protective layer PL. Detailed components of the cover window are described below with reference to FIG. 4.

The cover window 100 may be divided into a light transmitting area TT and a light blocking area BB, and the light transmitting area TT may overlap at least partially with the display area DA of the display panel PNL. For example, the light transmitting area TT may overlap the front surface of the display area DA or may overlap at least a part of the display area DA. Accordingly, the user may view the image through the light transmitting area TT or provide user input based on the image. However, the present disclosure is not limited thereto. For example, within the display area DA, an area where an image is displayed and an area where use input is detected may be separated from each other.

The peripheral area PA of the display panel PNL may at least partially overlap the light blocking area BB of the cover window 100. At least a part of the peripheral area PA may be covered by the light blocking area BB of the cover window 100.

The display device 1000 according to an embodiment may further include a hard coating layer HCAF disposed on the front surface of the cover window 100.

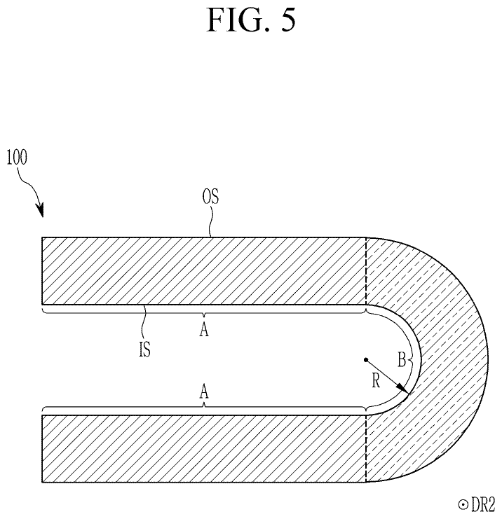

FIG. 4 is a top plan view illustrating the structure of an embodiment of the cover window 100 when the display device is not folded. FIG. 5 is a side view illustrating the structure of an embodiment of the cover window 100 when folded in the first direction DR1.

Referring to FIG. 4, the cover window 100 according to an embodiment includes a folding portion B that is bent when the cover window 100 is folded and a non-folding portion A that is not bent when the cover window 100 is folded. The cover window 100 may be folded about a folding axis extending in the second direction DR2, which may be perpendicular to the first direction DR1.

Referring to FIGS. 4 and 5, when the radius of curvature when the cover window 100 is folded is R, the length d of the folding portion B may be TTR. The radius of curvature R may be approximately 1 mm to approximately 2 mm but is not limited thereto.

Since the non-folding portion A is a portion that does not bend, the non-folding portion A may also be referred to as a flat portion or an even portion.

FIG. 5 shows the cover window 100 when folded and shows an inner surface IS, which is disposed on the inside and includes flat portions facing each other, and an outer surface OS disposed on the outside of the window 100. The inner surface IS is compressed during folding of the cover window 100, and the outer surface is tensioned during folding of the cover window 100.

When the display panel PNL is attached to the inner surface IS of the cover window 100, light forming an image may pass through the inner surface IS of the cover window 100 so that the image may be visible on the outer surface OS. That is, the outer surface OS of the cover window 100 may be a display surface.

According to another embodiment, when the display panel PNL is attached to the outer surface OS, light forming an image may pass through the outer surface OS of the cover window 100 so that the image may be visible on the inner surface IS. That is, the inner surface IS of the cover window 100 may be the display surface.

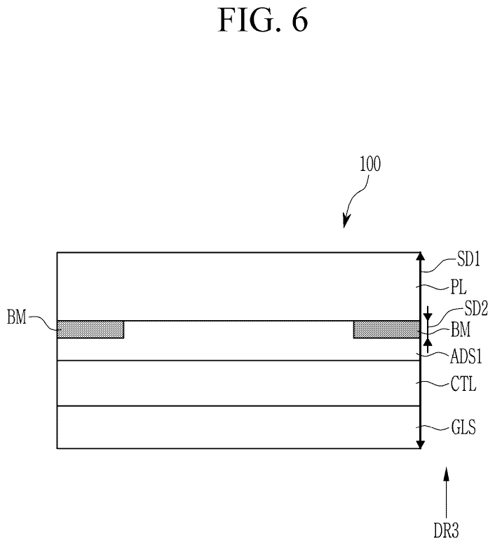

FIG. 6 is a cross-sectional view illustrating a cross-section of a cover window according to an embodiment. FIG. 6 shows an embodiment of the cover window 100 excluding the hard coating layer.

The cover window 100 may include the glass layer GLS, the coating layer CTL, the first adhesive layer ADS1, and the protective layer PL. The cover window 100 may further include a light blocking layer BM. Edges of the coating layer CTL and the first adhesive layer ADS1 may be aligned with a first side surface SD1 of the protective layer PL.

The glass layer GLS according to an embodiment may include glass. The glass included in the glass layer GLS may be a silicate type of glass. The glass layer GLS may be an overall thin or locally thin glass film UTG, but the glass layer GLS is not limited thereto. The thickness of the glass layer may be approximately 25 μm to 35 μm but is not limited thereto.

The coating layer CTL may be in contact with the upper surface of the glass layer GLS. The coating layer CTL may be coated on the glass layer GLS to improve the strength or breakage characteristics of the glass layer GLS and to reduce occurrences of bright spot defects in the cover window 100. The coating layer CTL and the glass layer GLS may be laminated.

The coating layer CTL may include a resin. The modulus of the coating layer CTL may be in a range from about 500 KPa to about 1 GPa. Specifically, the modulus of the coating layer CTL may be approximately 500 KPa at −20° C. and 1 GPa at 60° C. The elongation rate of the coating layer CTL may be 1.0% to 4.0% but is not limited thereto.

If the coating layer CTL is too thin, sufficient improvement of the impact resistance of the glass layer GLS may be difficult to achieve. Conversely, if the coating layer CTL is too thick, the glass layer GLS and the coating layer CTL may curl. In particular, the sum of the thicknesses of the glass layer GLS and the coating layer CTL being thicker than the protective layer PL, which is disposed on the coating layer CTL, may cause curling. Therefore, curling may be avoided or minimized by setting the thickness of the coating layer CTL based on the thickness of the protective layer PL. The thickness of the coating layer CTL may be 30 μm to 90 μm. When considering the curling, the thickness of the coating layer CTL may be 30 μm to 60 μm.

The first adhesive layer ADS1 may be disposed on the coating layer CTL. The first adhesive layer ADS1 may be in contact with the upper surface of the coating layer CTL. The first adhesive layer ADS1 may attach the coating layer CTL to the protective layer PL. The thickness of the first adhesive layer ADS1 may be approximately 25 μm to 50 μm.

The protective layer PL may be disposed on the first adhesive layer ADS1. The protective layer PL may be in contact with the upper surface of the first adhesive layer ADS1. The protective layer PL may include at least one of polymer resins such as polyethylene terephthalate (PET), polybutylene terephthalate (PBT), polycarbonate (PC), polyethylene naphthalate (PEN), polystyrene (PS), polymethylmethacrylate (PMMA), polyvinylchloride (PVC), polyethersulfone (PES), polypropylene (PP), and polyamide (PA).

The cover window 100 may further include the light blocking layer BM disposed between the protective layer PL and the first adhesive layer ADS1. A part of the light blocking layer BM may define at least one edge of the light transmitting area TT of the cover window 100. The light blocking layer BM may have a second side surface SD2 aligned with the first side surface SD1.

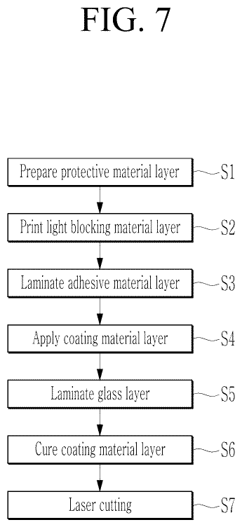

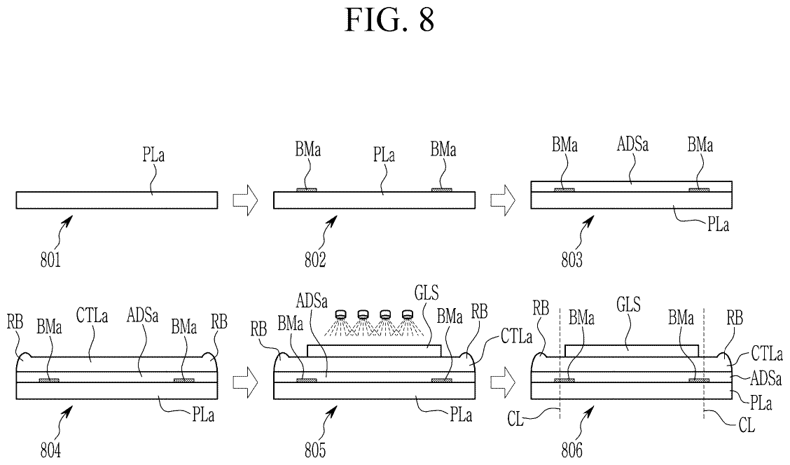

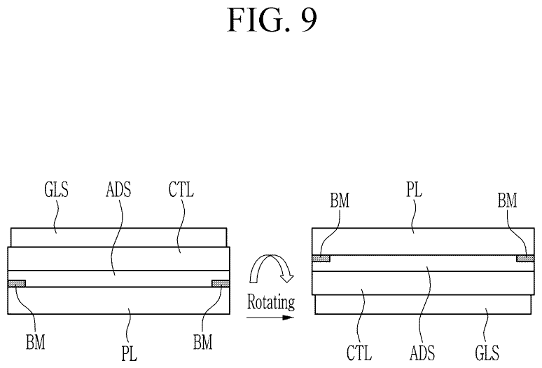

Hereinafter, a method of manufacturing a display device including a cover window is described with reference to FIGS. 7 to 9 along with the above-described drawings. FIG. 7 is a flowchart of a method of manufacturing a display device including a cover window. FIGS. 8 and 9 are cross-sectional views illustrating processes performed during the manufacturing a display device according to an embodiment.

First, a process S1 of FIG. 7 may prepare a protective material layer PLa as shown in a structure 801 of FIG. 8.

Thereafter, a process S2 of FIG. 7 may print a light blocking material layer BMa on the protective material layer PLa as shown in a structure 802 of FIG. 8.

Thereafter, a process S3 may laminate an adhesive material layer ADSa on the protective material layer PLa on which the light blocking material layer BMa is printed as shown in a structure 803 of FIG. 8. The adhesive material layer ADSa may be laminated on the protective material layer PLa through a coating process or a lamination process.

Thereafter, a process S4 applies a coating material layer CTLa on the adhesive material layer ADSa as shown in a structure 804 of FIG. 8. The coating material layer CTLa may have a thickness of approximately 30 μm to 90 μm. If curling of the coating layer and the glass layer is a concern, the coating material layer CTLa may be applied to a thickness of approximately 30 μm to 60 μm.

The coating material layer CTLa may include a resin bump portion RB at edges of the coating material layer CTLa. The coating material layer CTLa may include resin, and the resin bump portion RB may form at edges of the coating material layer CTLa due to the surface tension of the resin. The modulus of the coating material layer CTLa may be in a range from about 500 KPa to about 1 GPa.

A process S5 of FIG. 7 may laminate the glass layer GLS on the coating layer CTLa as shown in a structure 805 of FIG. 8. After laminating the glass layer GLS on the coating material layer CTLa, a process S6 of FIG. 7, e.g., UV curing, may be performed. In the process S5 of laminating the glass layer GLS on the coating material layer CTLa, the upper surface of the coating material layer CTLa may be flattened. UV curing during the process S6 may attach the coating material layer CTLa and the glass layer GLS, so that the coating material layer CTLa and the glass layer GLS may be combined.

Thereafter, a process S7 of FIG. 7 may simultaneously cut the protective material layer PLa, the adhesive material layer ADSa, and the coating material layer CTLa along cutting line CL shown in the structure 806 of FIG. 8. In this case, laser cutting may be used. The cutting process S7 may remove the resin bump portion RB. The cutting may be through the protective material layer PLa, the adhesive material layer ADSa, and the coating material layer CTLa in the thickness direction, and the cut line CL may define a perimeter of the cover window 100.

The edge of the glass layer GLS may be spaced apart from the cutting line CL or the cutting line CL may be on or within the boundaries of the glass layer GLS. Depending on the embodiment, the laser cutting process S7 may cut the glass layer GLS along the cutting line CL.

Since the blocking layer BMa, the adhesive layer ADSa, the control layer CTLa, and the glass layer GLS are sequentially stacked in order on the protective layer PL, the manufacturing method in accordance with the embodiment of FIG. 8 forms the cover window 100 upside down. Therefore, the cover window 100 formed as shown in FIG. 9 may be turned over and attached to the upper part of the display panel PNL during manufacture of a display device.

In a comparative embodiment, the coating layer CTL could be coated on the upper part of the glass layer GLS, but a manufacturing method in accordance with the comparative embodiment has limitations. In particular, there are limitations in setting the thickness of the coating layer CTL when spray coating, and there may be a disadvantage in that the resin bump portion RB at the edge is large when using the dispensing process or inkjet process. Additionally, if the side surfaces of the glass layer GLS are coated, wrinkles may appear at the edges after repeated folding, and defects may occur due to deformation of the flexible resin coated on the outside of the relatively hard glass layer GLS. When using the manufacturing method according to an embodiment of the present disclosure, a laser cutting step may be introduced to remove the resin bump portion RB caused by application of the coating layer CTL. Additionally, the thickness setting of the coating layer CTL may be freely chosen and set.

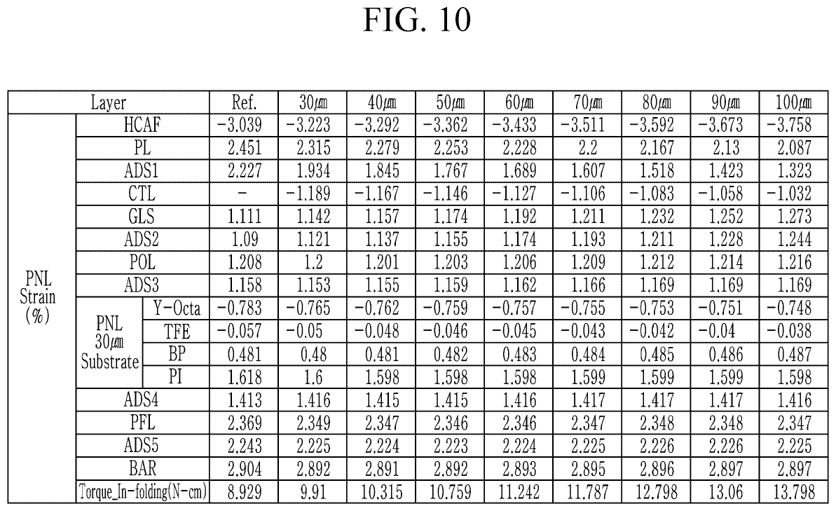

FIG. 10 is a table showing the degree of strain of each layer according to the force applied to the display device and the thickness of the coating layer CTL when the display device is folded.

A torque in folding value shown in FIG. 10 is a measurement of the force (stress) applied to the display device. In the case of a structure without the coating layer CTL, the force applied to the module is 8.929 N·cm. If the coating layer is 30 μm, the force applied to the module is 9.91 N·cm, if 40 μm, 10.315 N·cm, if 50 μm, 10.759 N·cm, if 60 μm, 11.242 N·cm, if 70 μm, 11.787 N·cm, if 80 μm, 12.397 N·cm, if 90 μm, 13.06 N·cm, and if 100 μm, 13.798 N·cm. It can be seen that the thicker the coating layer, the greater the thickness of the module, which increases the stress on the module, i.e. the folding force.

When the coating layer CTL is coated on the glass layer GLS, the folding force increases and the degree of deformation of the glass layer GLS may increase. This is because the repulsive force increases when folding.

The table in FIG. 10 shows the degree to which each layer is deformed when the module is folded with a curvature radius of 1.4 mm at the folding area.

If the coating layer CTL is 30 μm, the glass layer GLS with a thickness of about 30 μm may be stretched by 1.142% of its original length. The thickness of the coating layer CTL is 40 μm, the glass layer GLS may be stretched by 1.157%, if 50 μm, 1.174%, if 60 μm, 1.192%, if 70 μm, 1.211%, if 80 μm, 1.232%, if 90 μm, 1.252%, if 100 μm, 1.273%. However, there is a limit to stretching the glass layer GLS, and if the glass layer GLS stretches by 1.26% or more, damage may occur.

Therefore, when setting the thickness of the coating layer CTL, the degree of improvement in the impact resistance of the glass layer GLS increases as the coating layer CTL becomes thicker, but considering the degree of deformation of the glass layer GLS, it may be advantageous to have the coating layer CTL with a thickness of 90 μm or less. However, as described above, in order to prevent curling, it may be advantageous to have the coating layer CTL with a thickness of 60 μm or less.

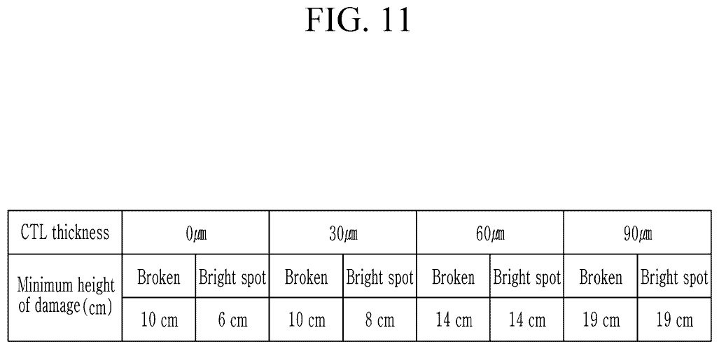

FIG. 11 is a table showing the effect of improving the impact resistance of the glass layer when introducing a coating layer.

An experiment was conducted to measure the height at which damage and bright spots occur when a pen is dropped on a display device. A pen with a pen tip diameter of 0.3 mm and a weight of approximately 5.6 g was used. The height measured below corresponds to the average value of the minimum height at which damage occurs, and the height is based on the uppermost surface of the display device.

In the case where there was no coating layer CTL, damage occurred when the pen was dropped from a height of 10 cm, and a bright spot occurred at a height of 6 cm.

When the coating layer CTL was 30 μm, damage occurred when the pen was dropped from a height of 10 cm relative to the panel, and a bright spot occurred in the display area at a height of 8 cm. When the thickness of the coating layer CTL was 30 μm, it can be seen that the damage of the glass layer GLS is at the same level, but the bright spot of the display area is improved.

When the coating layer CTL was 60 μm, damage occurred when the pen was dropped from a height of 14 cm relative to the panel, and a bright spot occurred at a height of 14 cm. It can be seen that when the thickness of the coating layer CTL was 60 μm, both the damage and bright spot of the glass layer GLS are improved.

When the coating layer CTL was 90 μm, damage occurred when the pen was dropped from a height of 19 cm relative to the panel, and a bright spot occurred at a height of 19 cm. When the thickness of the coating layer CTL was 90 μm, both the damage and bright spot of the glass layer GLS were improved.

A display device according to an embodiment may be applied to various electronic devices. An electronic device according to an embodiment may include the display device, and may further include modules or devices having additional functions other than the display device.

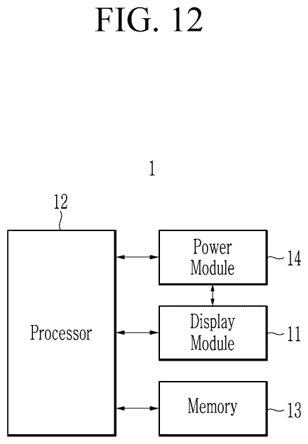

FIG. 12 is a block diagram of an electronic device according to some embodiments. Referring to FIG. 14, the electronic device 1 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 15 may store data information necessary for operations of the processor 12 or the display module 11. When the processor 12 executes an application stored in the memory 15, video data signals and/or input control signals are transmitted to the display module 11, and the display module 11 can process the received signals to output video information through the display screen.

The power module 14 may include a power supply module such as a power adapter or battery device, and a power conversion module that converts the power supplied by the power supply module to generate the power necessary for the operation of the electronic device 1.

At least one of components of the electronic device 1 may be included within the display device according to the above-described embodiments. Additionally, some of the individual modules that are functionally included within a single module may be incorporated into the display device, while others may be provided separately from the display device. For example, the display device may include the display module 11, while the processor 12, memory 13, and power module 14 may be provided in a form of other devices within the electronic device 1 that are not part of the display device.

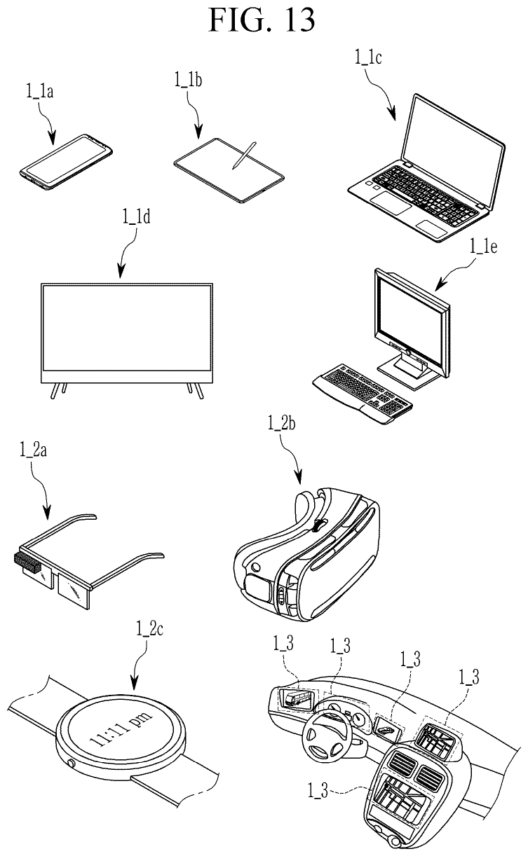

FIG. 13 shows schematic diagrams of electronic devices according to various embodiments.

Referring to FIG. 13, various electronic devices with the display device according to the embodiments may include not only image display electronic devices such as smartphones 1_1a, tablet PCs 1_1b, laptops 1_1c, TVs 1_1d, desktop monitors 1_1e, but also wearable electronic devices with display modules such as smart glasses 1_2a, head-mounted displays 1_2b, smart watches 1_2c, as well as automotive electronic devices with display modules 1_3 such as those placed on car dashboards, center fascias, CID (Center Information Display), room mirror displays, and so on.

While the embodiments of the present disclosure have been described in detail, the disclosure is not limited to the disclosed embodiments, but to the contrary, the disclosure is intended to cover various modifications and equivalent arrangements included within the spirit and scope of the appended claims.

What is claimed is:

1. A display device, comprising:
a display panel including a folding area and a non-folding area; and
a cover window disposed on the display panel and including a folding portion and a non-folding portion,
wherein the cover window comprises:
a glass layer;
a coating layer disposed on the glass layer;
an adhesive layer disposed on the coating layer; and
a protective layer disposed on the adhesive layer, wherein
the thickness of the coating layer is 30 μm to 90 μm,
edges of the protective layer, the adhesive layer, and the coating layer are aligned at a first side surface,
the folding portion includes an inner surface that is compressed when folded and an outer surface that is stretched when folded,
the folding portion overlaps the folding area, and
the non-folding portion overlaps the non-folding area.

2. The display device of claim 1, wherein
a thickness of the coating layer is in a range from 30 μm to 60 μm.

3. The display device of claim 2, wherein
the coating layer includes a resin,
and a modulus of the coating layer is in a range from 500 KPa to 1 GPa.

4. The display device of claim 2, wherein
an elongation rate of the coating layer is in a range from 1.0% to 4.0%.

5. The display device of claim 2, wherein
a thickness of the glass layer is in a range from 25 μm to 35 μm.

6. The display device of claim 2, wherein
a thickness of the adhesive layer is in a range from 25 μm to 50 μm.

7. The display device of claim 2, wherein
a thickness of the protective layer is in a range from 50 μm to 80 μm.

8. The display device of claim 2, further comprising
a light blocking layer between the protective layer and the adhesive layer, wherein a part of the light blocking layer defines at least one edge of a light transmitting area of the cover window.

9. The display device of claim 8, wherein
the light blocking layer has a second side surface aligned with the first side surface.

10. The display device of claim 2, wherein
the coating layer is in contact with the upper surface of the glass layer.

11. The display device of claim 2, wherein
the adhesive layer is in contact with the upper surface of the coating layer.

12. The display device of claim 2, wherein
the protective layer is in contact with the upper surface of the adhesive layer.

13. A method of manufacturing a device including a cover window, the method comprising:
printing a light blocking material layer on a protective material layer;
laminating an adhesive material layer on the protective material layer;
applying a coating material layer on the adhesive material layer;
laminating a glass layer on the coating material layer;
curing the coating material layer; and
simultaneously laser cutting the protective material layer, the adhesive material layer, and the coating material layer along a cutting line to form the cover window.

14. The method of claim 13, wherein
the coating material layer includes a resin bump portion,
and the laser cutting removes the resin bump portion.

15. The method of claim 14, wherein
the laser cutting line cuts through the protective material layer, the adhesive material layer, and the coating material layer in a thickness direction.

16. The method of claim 14, wherein
in the laser cutting, the edge of the glass layer is spaced apart from the cutting line.

17. The method of claim 14, wherein
in the laser cutting, the glass layer is also laser cut along the cutting line.

18. The method of claim 14, wherein
the coating material layer has a thickness in a range from 30 μm to 90 μm.

19. The method of claim 14, wherein
the coating material layer includes a resin,
and a modulus of the coating material layer is in a range from 500 KPa to 1 GPa.

20. An electronic device comprising:
a memory;
a processor executing an application stored in the memory; and
a display device comprising a display module outputting video information provided by the application, wherein
the display device comprising:
a display panel including a folding area and a non-folding area; and
a cover window disposed on the display panel and including a folding portion and a non-folding portion,
wherein the cover window comprises:
a glass layer;
a coating layer disposed on the glass layer;
an adhesive layer disposed on the coating layer; and
a protective layer disposed on the adhesive layer, wherein
the thickness of the coating layer is 30 μm to 90 μm,
edges of the protective layer, the adhesive layer, and the coating layer are aligned at a first side surface,
the folding portion includes an inner surface that is compressed when folded and an outer surface that is stretched when folded,
the folding portion overlaps the folding area, and
the non-folding portion overlaps the non-folding area.
